(19) United States
(12) Patent Application Publication
(10) Pub. No.: US 2007/0097628 A1
(43) Pub. Date: May 3, 2007

(54) Heat dissipation apparatus for multiple housing devices

(76) Inventor: Martin R. Pais, N. Barrington, IL (US)

Correspondence Address: MOTOROLA INC, 600 NORTH US HIGHWAY 45, ROOM AS437, LIBERTYVILLE, IL, 60048-5343, US

(21) Appl. No.: 11/263,457

(22) Filed: Oct. 31, 2005

(51) Int. Cl. H05K 7/20

(52) U.S. Cl. 361/695

(57) ABSTRACT

A handheld device (100) having means for dissipating heat is disclosed. The device comprises a first housing (102) having a first vent (112) and at least one heat-generating component (406). The device also comprises a second housing (104) having a second vent and a fan. A coupling that provides movement of the first housing and the second housings relative to one another. The coupling having an air flow passage between the first and second housings. The fan of the second housing induces air heated by the at least one heat-generating component to flow from the first housing.

### FIELD OF THE INVENTION

The present invention relates generally to the field of heat dissipation and in particular to heat dissipation in multiple housing portable devices.

### BACKGROUND OF THE INVENTION

As portable electronic devices incorporate faster microprocessors to accommodate higher data rates, larger displays and the like, heat generated by the electronic components increases also increases. Wireless communication devices, for example, incorporating multimedia functions such as audio streaming, TV broadcast reception and the like will increase the heat generation. This in turn causes the external surfaces of the device to reach uncomfortably warm temperatures, particularly for handheld devices.

Many of these portable devices are handheld, foldable clams shell devices wherein most of the heat generating components are housed in one of two or more housings for ease of manufacturing such as to limit the number of connections between multiple housings and the number of circuit boards needed to couple components together. Clam shell devices have the same electronics in general as candy bar from factor devices, however the same components are all or substantially all carried in one of the two housings, i.e. one half the clam shell, resulting in a smaller area carrying the same number of heat generating components. Thus, the smaller surface area increases the external surface temperature even further.

Some devices place a fan on the hot component in order to dissipate the heat. For example, fans are placed on some microprocessors in computers to keep the microprocessor cool. This, however, only cools the one component. Additionally, portable devices, handheld in particular, are continuously facing size constraints limiting the internal space for such cooling devices.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 illustrates a perspective view of an exemplary handheld device.

FIG. 2 illustrates an exemplary second housing exploded view of the handheld device.

FIG. 3 illustrates an exemplary first housing exploded view of the handheld device.

FIG. 4 illustrates an exemplary circuit board that is carried in the housing.

FIG. 5 illustrates an exemplary cross section of a housing and fan.

FIG. 6 illustrates an exemplary cross section of a housing and fan.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE PREFERRED EMBODIMENTS

While the present invention is achievable by various forms of embodiment, there is shown in the drawings and described hereinafter several examples of embodiments with the understanding that the present disclosure is to be considered an exemplification of the invention and is not intended to limit the invention to the specific embodiments contained herein as will become more fully apparent from the discussion below. It is further understood that the heat dissipation method and apparatus of the present invention may be used more generally in any application where it is desirable to provide environment control.

A handheld device having a means for dissipating heat is disclosed. The device comprises a first housing having a first vent and at least one heat-generating component. The device also comprises a second housing having a second vent and a fan. The first housing is coupled to the second housing by a coupling that provides movement of the first housing and the second housings relative to one another. The coupling has an air flow passage between the first and second housings. The fan of the second housing induces air heated by the at least one heat-generating component to flow from the first housing.

Before describing in detail exemplary embodiments that are in accordance with the present invention, it should be observed that the embodiments reside primarily in combinations of components related to heat dissipation. Accordingly, the apparatus components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

It is understood that the use of relational terms, if any, such as first and second, top and bottom, and the like are used solely to distinguish one from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element. The terms “a” and “an” mean at least one. The term “exemplary” is intended to mean one example of the invention.

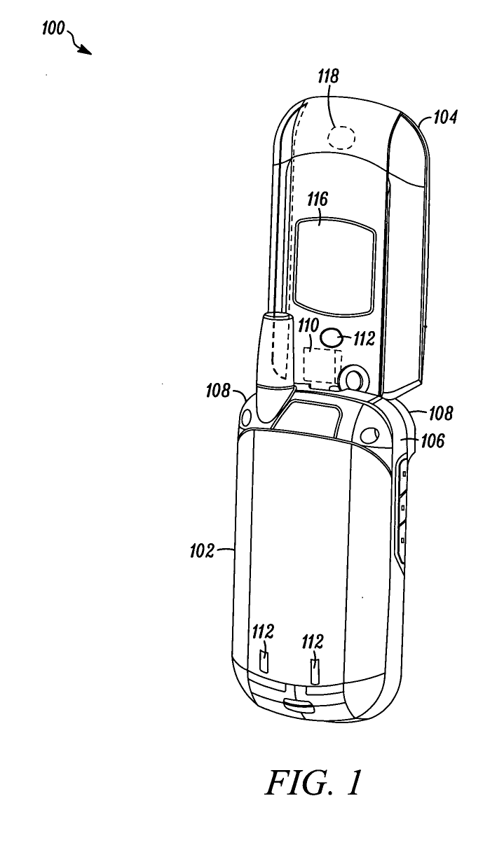

FIG. 1 illustrates a perspective view of an exemplary handheld device 100 having a first housing 102 and a second housing 104. The first housing 102 and the second housing 104 are movably coupled together such that the first housing 102 moves relative to second housing 104. In this exemplary embodiment, the first housing 102 is coupled by a coupling 106 to the second housing 104. For example, a hinge, such as an exemplary single axis hinge may movably couple the first housing 102 to the second housing 104. The first housing has a first housing coupling portion 108. In this embodiment, the first housing coupling portion 108 comprises two hinge knuckles. The second housing 104 in this embodiment is a flip or cover that rotates about an axis of the coupling 106 from an open to a closed, folded, configuration such that they are stacked adjacently relative to one another. In an alternative embodiment, the first and second housing may slide relative to one another from an open and closed position. The coupling 106 provides movement of the first and second housings relative to one another, and the coupling provides an air flow passage between the first and second housings. The air flow passage extends between the first housing 102 and the second housing 104.

In this exemplary embodiment, the handheld device is a wireless communication device such as a radiotelephone handset. The radiotelephone described herein is a representation of the type of wireless communication device that may benefit from the present invention. However, it is to be understood that the present invention may be applied to any type of multiple housing, hand-held or portable device including, but not limited to, the following devices: radiotelephones, cordless phones, paging devices, personal digital assistants, portable computers, pen-based or keyboard-based handheld devices, remote control units, portable media players (such as an MP3 or DVD player) and the like. Accordingly, any reference herein to the wireless communication device or radiotelephone 100 should also be considered to apply equally to other handheld or portable electronic devices.

FIG. 1 illustrates a fan 110, shown in dotted line format, which is carried in the second housing 104. The second housing 104 has a vent to allow air to pass between the inside of the housing and the outside. The second housing 104 may have one vent or a plurality of vents. In this exemplary embodiment, the second housing 104 includes a first vent 112. The fan 110 induces air to flow thought the first vent 112. The fan 110 is directly coupled or indirectly coupled to the first vent 112. The position of the vent 112 within the second housing 104 may be located to cause the air to flow through the second housing 104 in a desired direction. For example, the position of the vent 112 in this exemplary embodiment, directs air out of the second housing 104 away from the user when the device is positioned up against the user's ear.

The first housing 102 has a vent to allow air to pass between the inside of the housing and the outside of the housing. The first housing 102 may have one vent or a plurality of vents as with the second housing 104. In this exemplary embodiment, the first housing 102 carries a plurality of second vents 114.

In this exemplary embodiment, the first vent 112 is an exhaust and the plurality of second vents 114 provide air inlets and therefore air flow is directed from the first housing 102 to the second housing 104. The fan 110 induces air to enter through the plurality of second vents 114 into the first housing 102, flow adjacent to the components and through the coupling 106 into the second housing 104 and exit the through the first vent 112. It is to be understood that the direction of air flow is in this embodiment is one example, and that the air may b directed to flow from the second housing 104 to the first housing 102. In the exemplary embodiment of FIG. 1, the second housing 104 carries the fan 110 and optionally a display 116 or a speaker 118 or both in this embodiment. It is to be understood that other components may be carried in the second housing 104. Some handheld devices, flip or clamshell type device in particular, generally carry the electronic circuits such as the microprocessor, memory, transmitters and receivers, amplifiers and the like in one housing as they are all connected via a printed circuit board, limiting the number of connections that need to be carried from the first housing 102 to the second housing 104, and as a result limits the space available in the housing.

It is to be understood that one skilled in the art will appreciate that there are many fans and fan modules available. For example, the fan 110 may be a vane axial fan, a radial fan, a mixed flow fan or the like. The fan may be a fan module that comprises a fan blade, a motor and a housing. It is to be understood that there are various way of securing the fan in the housing. For example, the fan may be screwed, glued, press-fit or the like into the second housing 104. The orientation of the fan within the housing may depend on the amount of space available and the type of fan used. For example, a vane axial fan may be placed so that a long axis of the fan runs from a front to back of the device housing. In another embodiment, the fan may be a radial fan wherein the long axis of the fan may run parallel to the long axis of the device housing. The first housing (102) and the second housing 104 may have air guides that channel the air flow as induced by the fan 110. The fan in the second housing (104), which is the flip housing of the handheld device, directs the airflow, and the heated air away from the user.

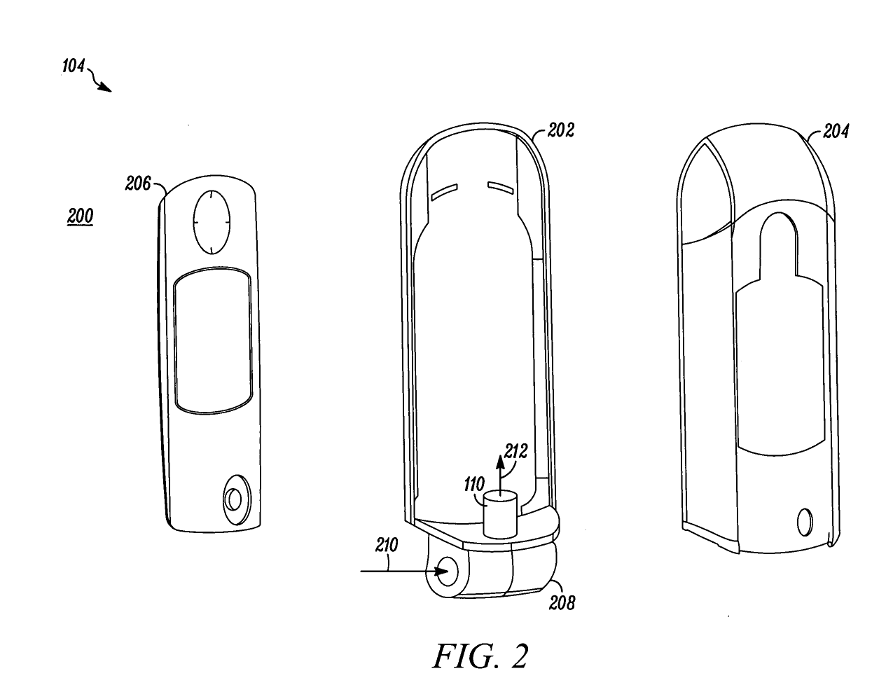

FIG. 2 illustrates an exemplary second housing exploded view 200 of the handheld device 100. The second housing 104 is comprised of a body 202, a first cover 204 and a second cover 206. The fan 110 is carried on the body 202. In this embodiment, the fan 110 is carried adjacent to the hinge 106. The second housing 104 has a second housing coupling portion 208 which couples to the complimentary first housing coupling portion 108. The second housing coupling portion 208 has an air passage 210 that allows air to move from the first housing 102 to the second housing 104, in which the air flow is induced by the fan 110.

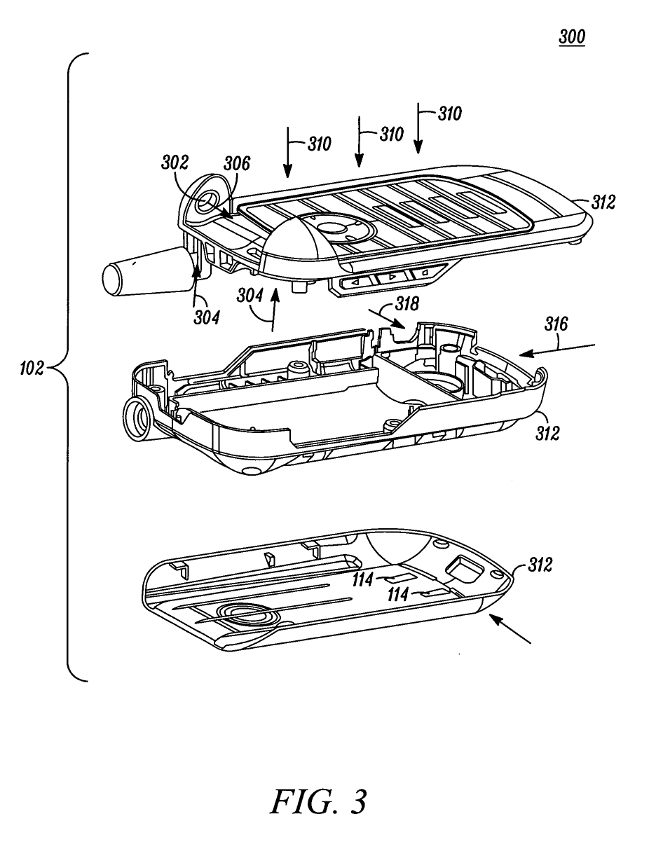

FIG. 3 illustrates an exemplary first housing exploded view 300 of the handheld device 100. The exemplary exploded view 300 shows the first housing coupling portion 108 which has a first housing portion air passage 302. The first housing portion air passage 302 aligns with the second housing air passage 210 to allow air to flow between the first housing 102 and the second housing 104. The first housing portion air passage 302 enter from the first housing 102 in the direction indicated by arrows 304 and into the second housing air passage indicated by arrow 306.

Also shown in FIG. 3 are optional air vents. For example, the vents may be positioned between the keys of the keypad creating keypad vents 308 that allow air to flow into the first housing 102 in the direction indicated by arrows 310. Another alternative location for air vents in the first housing 102 are at the device bottom 312 wherein the device 100 has a connector (not shown). Air flows in the connector vent 314 indicated by the arrow 316. Yet another alternative location for air vents is a side connector wherein air flows into the side as indicated by arrow 318. It is to be understood that the locations are exemplary and not independent as all, or any combination of the vents may be present.

The fan 110 may also be located in the coupling 106 and not necessarily in the main body of the second housing 104. The fan 110 may be located in a second housing coupling portion or a first housing coupling portion. For example when the hinge 106 has a first hinge portion coupled to or extending from the first housing 102 that engages a second hinge portion coupled to or extending from the second housing that integrally form the hinge 106, the fan 110 may be placed in either hinge portion inducing air to flow between the two housings through the hinge.

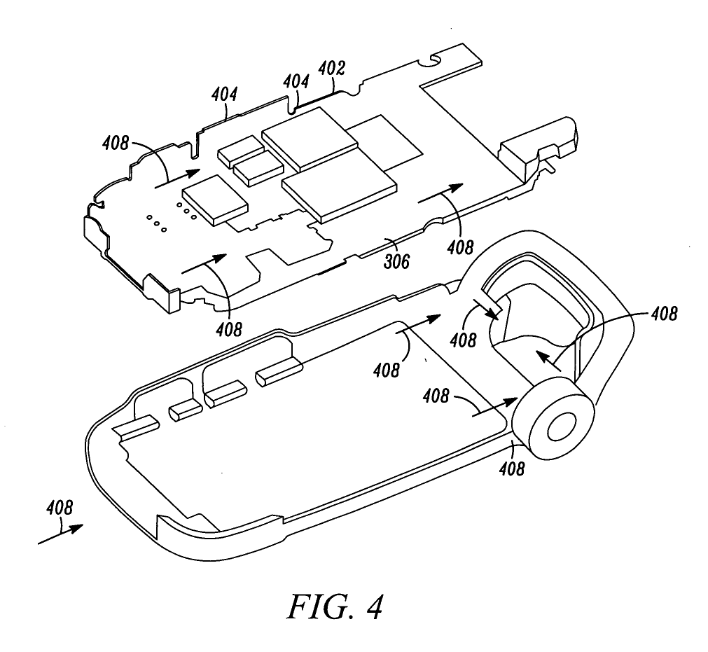

FIG. 4 illustrates an exemplary circuit board 402 that is carried in the first housing 102. The circuit board 402 carries circuit components 404 wherein at least one of which is a heat generating component 406. The circuit board 402 dissipates heat from the at least one heat generating component. Air flow, indicated by arrows 408, over the circuit board 402 and the circuit components 404 provides heat transfer, transporting air heated by the heat generating components, out from the first housing 102 thereby producing a cooling effect.

In this embodiment, the air flow direction is such that air enters the first housing 102 though the plurality of second vents 114 therein, and flows adjacent to the circuit board 402 and the circuit components 402, through the first housing air passage 302 and the second housing air passage 210 of the coupling 106, and out through the first vent 112 of the second housing 104. The fan 110 may also be configured to induce airflow in other directions and is not limited to the airflow pattern of this exemplary embodiment. For example, air may enter through the first vent 112 of the second housing 104, pass through the air passage of the coupling 106, pass over the circuit components 302 and out through the plurality of second vents 114 in the first housing 102.

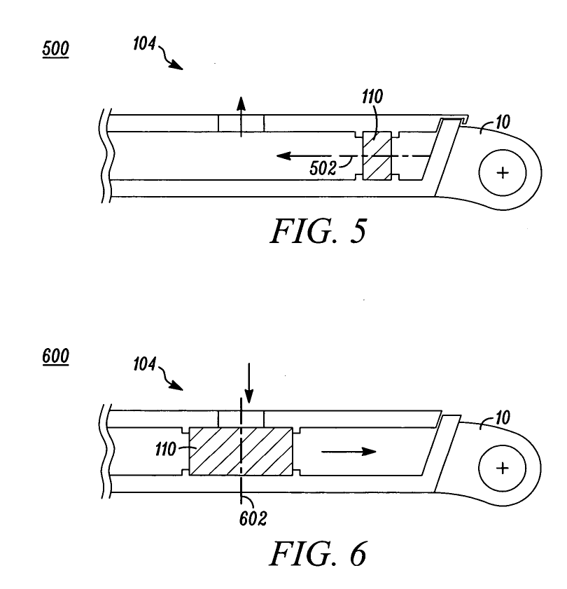

The fan 110 may be configured within the second housing 104 in one of many configurations. The fan configuration within the second housing 104 may be a function of the type of fan 110. In one exemplary embodiment illustrated in FIG. 5, a vane-axial fan is shown in a first fan configuration 500. In this configuration 500, the fan 110 is positioned such that the direction of air flow is parallel to the axis of rotation 502. In this embodiment, the air flow is directed towards or away from the hinge 208 depending on the direction of the fan rotation. The position of the fan 110 within the housing 104 may be adjacent to the second housing coupling portion 208 as shown in FIG. 5. Alternatively, the fan 110 may be positioned away from the second housing coupling portion 208 or the fan 110 may be positioned within the second housing coupling portion 208. For example the fan 110 may be positioned in the first housing coupling portion 108, which is a hinge knuckle in one embodiment, of the hinge or a hinge barrel of the hinge 208 which is the second housing coupling portion in this exemplary embodiment.

FIG. 6 illustrates a radial fan in a second fan configuration 600. In this configuration 600, the fan 110 is positioned such that the axis of rotation 602 and thereby the air flow is directed into or out of the first cover 204, the second cover 206 pr both. This configuration is suited for devices with thin housings, such as radiotelephone flips for example, as the short dimension of the fan 110 accommodates the thin housing. The radial fan has an exhaust direction perpendicular to axis of rotation. Therefore in this embodiment, air is drawn into the fan from the first vent 112 and the exhaust is directed toward the hinge inside of the housing.

While the preferred embodiments of the invention have been illustrated and described, it is to be understood that the invention is not so limited. Numerous modifications, changes, variations, substitutions and equivalents will occur to those skilled in the art without departing from the spirit and scope of the present invention as defined by the appended claims.

What is claimed is:

1. A wireless communication device having means for dissipating heat comprising:
a first housing having at least one heat-generating component;
a second housing, movably coupled to the first housing, having a fan,
wherein the fan of the second housing transports air heated by the at least one heat-generating component from the first housing; and
a vent in one of the first housing or the second housing.

2. The wireless communication device of claim 1, further comprising a temperature sensor.

3. The wireless communication device of claim 1, a second vent in one of the first housing or the second housing whichever the first vent is not.

3. The wireless communication device of claim 1, wherein the first and second vents are located at a back portion or a side portion of the first and second housings, respectively.

4. The wireless communication device of claim 1, wherein the first housing includes a user interface that includes the first vent.

5. The wireless communication device of claim 1, wherein the fan is configured to induce air flow into the first housing though the second vent adjacent to a circuit components through a first housing air passage and a second housing air passage of a coupling and out through the first vent of the second housing.

6. The wireless communication device of claim 1, wherein the fan is a vane-axial fan or a radial fan.

7. A wireless communication device having means for dissipating heat comprising:
a first housing portion;
a second housing portion;
a heat dissipating components carried in the first housing;
a fan carried in the second housing portion; and
a coupling to couple the first housing to the second housing, the coupling having an air passage that extends between the first housing and the second housing.

8. The wireless communication device of claim 7, further comprising a first vent in the first housing and a second vent in the second housing.

9. The wireless communication device of claim 7, a keypad having at least one vent.

10. The wireless communication device of claim 7, wherein the fan is located in the knuckle.

11. A wireless communication device having means for dissipating heat comprising:
a first housing having a first vent and at least one heat-generating component;
a second housing having a second vent and a fan; and
a coupling providing movement between the first and second housings, the coupling having an air flow passage between the first and second housings.
